(19) United States
(12) Patent Application Publication
(10) Pub. No.: US 2015/0129025 A1
(43) Pub. Date: May 14, 2015

(54) HIT SOLAR CELL

(71) Applicant: INDUSTRIAL TECHNOLOGY RESEARCH INSTITUTE, Hsinchu (TW)

(72) Inventors: Yu-Hung CHEN, Hsinchu (TW); Jun-Chin LIU, Hsinchu (TW); Yung-Tsung LIU, Hsinchu (TW); Chen-Cheng LIN, Hsinchu (TW)

(73) Assignee: INDUSTRIAL TECHNOLOGY RESEARCH INSTITUTE, Hsinchu (TW)

(21) Appl. No.: 14/163,259

(22) Filed: Jan. 24, 2014

(30) Foreign Application Priority Data
Nov. 8, 2013 (TW) 102140641

(51) Int. Cl. H01L 31/077

(52) U.S. Cl. CPC H01L 31/077
USPC 136/256; 136/258

(57) ABSTRACT

A HIT solar cell is provided, including a p-type crystalline silicon substrate having a light-receiving surface, a first intrinsic amorphous silicon thin-film layer formed on the light-receiving surface of the p-type crystalline silicon substrate, an n-type amorphous oxide layer formed on the first intrinsic amorphous silicon thin-film layer, and a first transparent conductive layer formed on the n-type amorphous oxide layer. In the HIT solar cell, the n-type amorphous oxide layer can be directly formed, without forming the first intrinsic amorphous silicon thin-film layer, and the n-type amorphous oxide layer can be divided into an n⁻-type amorphous oxide layer and an n⁺-type amorphous oxide layer that are formed sequentially.

### CROSS-REFERENCE TO RELATED APPLICATIONS

This application claims priority to Taiwanese Patent Application No. 102140641, filed on Nov. 8, 2013. The entirety of the above-mentioned patent application is hereby incorporated by reference herein and made a part of this specification.

### TECHNICAL FIELD

The present disclosure relates to solar cells, and, more particularly, to a HIT solar cell.

### BACKGROUND

As shown in FIG. 1, a conventional heterojunction with intrinsic thin-layer (HIT) solar cell comprises a p-type crystalline silicon substrate 10 having a light-receiving surface 102 and a light-against surface 101, and intrinsic amorphous silicon layers 12 and 11 formed on the light-receiving surface 102 and the light-against surface 101, respectively. An n-type amorphous silicon layer and a p-type amorphous silicon layer are formed on the intrinsic amorphous silicon layers 12 and 11, respectively. A transparent conductive layer 16 and conductive terminal 18 are formed on the n-type amorphous silicon layer 14. Another transparent conductive layer 15 and an electrode layer 17 are formed on the p-type amorphous silicon layer 13. Since this type of stacking structure of the solar cell has heterojucntion with intrinsic silicon layer and therefore is called Heterojunction with Intrinsic Thin-layer solar cell (HIT).

In the HIT solar cell, the amorphous silicon layer, such as the intrinsic amorphous silicon layer 12 and the n-type amorphous silicon layer 14 formed on the light-receiving surface 102 of the p-type crystalline silicon substrate 10, has the drawbacks of poor light absorption and low transmittance, resulting in the reduction/*n of the number of the photo-generated charge carriers excited by light. In addition, it is easy to cause plasma damage on the silicon substrate during the fabricating process using traditional plasma-enhanced chemical vapor deposition (PECVD) technology, resulting in lower short circuit current, and leading to lower conversion efficiency.

As shown in FIG. 4, another conventional solar cell comprises a p-type nanocrystalline silicon layer 40 having a light-receiving surface 402 and a light-against surface 401. An intrinsic nanocrystalline silicon layer 41a, an n-type nanocrystalline silicon layer 41b, a second transparent conductive layer 43, and a silver layer 45 are formed on the light-against surface 401 sequentially. An intermediate reflector layer 42, n-type amorphous silicon layer 44a, an intrinsic amorphous silicon layer 44b, a p-type amorphous silicon layer 44c, a first transparent conductive layer 46, and a glass substrate 48 are formed on the light-receiving surface 402 sequentially.

However, the n-type nanocrystalline silicon layer 41b and the intermediate reflector layer 42 also possess drawbacks of poor light absorption and low transmittance. More specifically, the intermediate reflector layer is provided in order to reach current matching between the top cell (amorphous silicon layer) and the bottom cell (nanocrystalline silicon layer), so as to allow the light to be reflected to the top cell. However, for electrical advantages, to reduce the series resistance between the top and the bottom cell, the intermediate reflector layer needs to be thicker, causing insufficient light to reach the bottom cell, causing unmatched of the current.

As shown in FIG. 6, another solar cell is shown. The solar cell comprises the substrate 60, a metallic back contact layer 61, a p-type absorber 62, a buffer layer 63, a thin-film 64, a transparent conductive layer 65, and a conductive terminal 66. The same drawbacks of poor light absorption and low transmittance still exist. Thus, there is an urgent need to solve the problems experienced in the prior art.

### SUMMARY

The present disclosure provides a heterojunction with intrinsic thin-layer (HIT) solar cell, comprising: a p-type crystalline silicon substrate having a light-receiving surface; a first intrinsic amorphous silicon thin-film layer formed on the light-receiving surface of the p-type crystalline silicon substrate; an n-type amorphous oxide layer formed on the first intrinsic amorphous silicon thin-film layer; and a first transparent conductive layer, formed on the n-type amorphous oxide layer.

The present disclosure provides another HIT solar cell, comprising: a p-type crystalline silicon substrate having a light-receiving surface; an n-type amorphous oxide layer formed on the light-receiving surface of the p-type crystalline silicon substrate; and a first transparent conductive layer formed on the n-type amorphous oxide layer.

The present disclosure provides yet another HIT solar cell, comprising: a p-type nanocrystalline silicon layer having a light-receiving surface and an opposing light-against surface; a first silver nanowire layer formed on the light-receiving surface of the p-type nanocrystalline silicon layer; a first n-type amorphous oxide layer formed on the first silver nanowire layer; an intrinsic nanocrystalline silicon thin-film layer formed on the light-against surface of the p-type nanocrystalline silicon layer; a second n-type amorphous oxide layer formed on the intrinsic nanocrystalline silicon thin-film layer; and a second silver nanowire layer formed on the second n-type amorphous oxide layer.

The present disclosure further provides a solar cell, comprising: an n-type amorphous oxide layer having a light-receiving surface; and a silver nanowire layer formed on the light-receiving surface of the n-type amorphous oxide layer.

### BRIEF DESCRIPTION OF DRAWINGS

The present disclosure can be more fully understood by reading the following detailed description of the preferred embodiments, with reference made to the accompanying drawings, wherein:

FIG. 1 is a cross-sectional view of a conventional HIT solar cell;

FIG. 2 is a cross-sectional view of a HIT solar cell in accordance with a first embodiment of the present disclosure;

FIG. 3 illustrates cross-sectional views of two types of the HIT solar cells in accordance with a second embodiment of the present disclosure;

FIG. 4 is a cross-sectional view of another conventional solar cell;

FIG. 5 is a cross-sectional view of the solar cell in accordance with a third embodiment of the present disclosure;

FIG. 6 is a cross-sectional view of yet another conventional HIT solar cell; and

FIG. 7 is a cross-sectional view of the HIT solar cell in accordance with a fourth embodiment of the present disclosure.

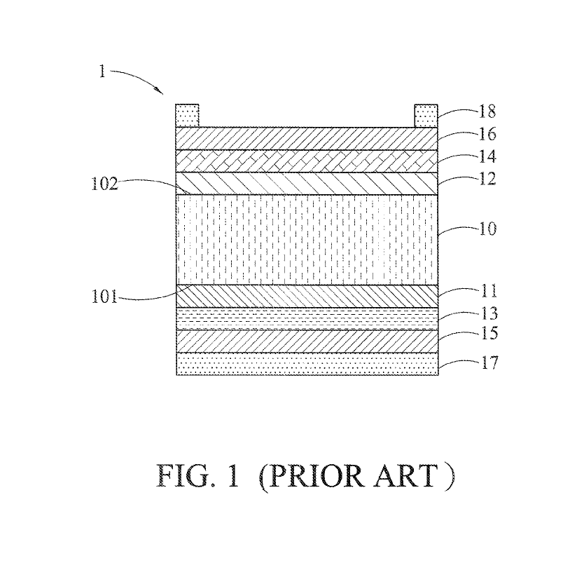

### DETAILED DESCRIPTION

In the following detailed description, for purposes of explanation, numerous specific details are set forth in order to provide a through understanding of the disclosed embodiments. It will be apparent, however, that one or more embodiments may be practiced without these specific details. In other instances, well-known structures and devices are schematically shown in order to simplify the drawing.

### First Embodiment

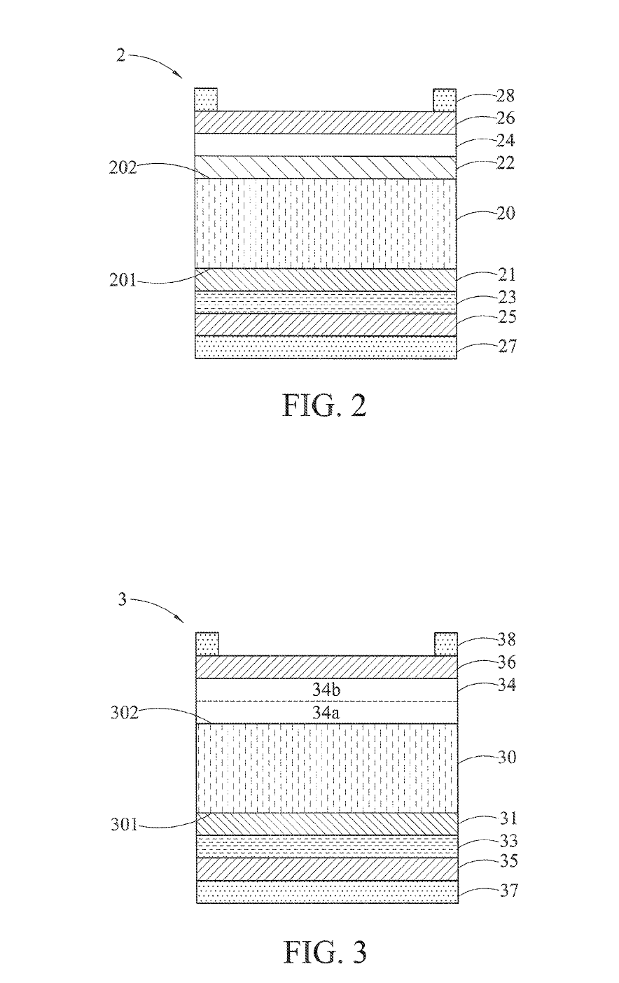

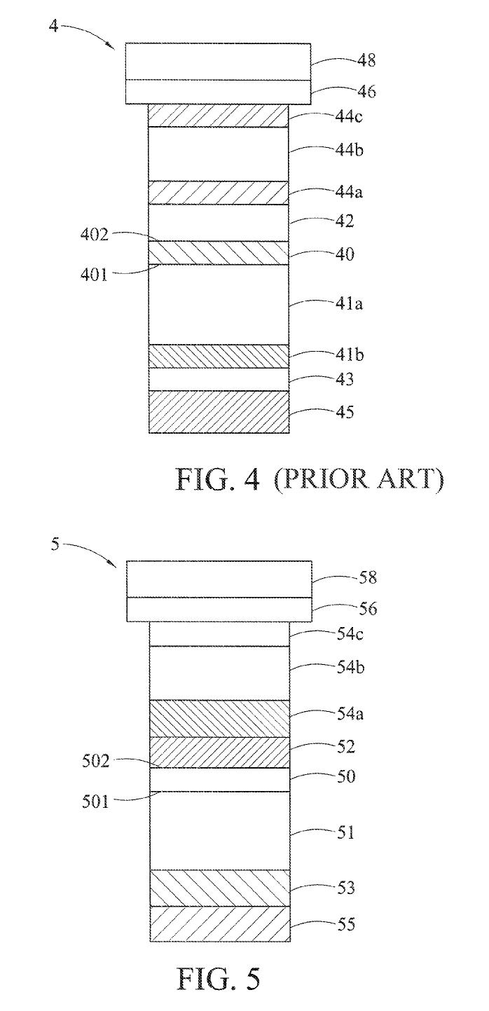

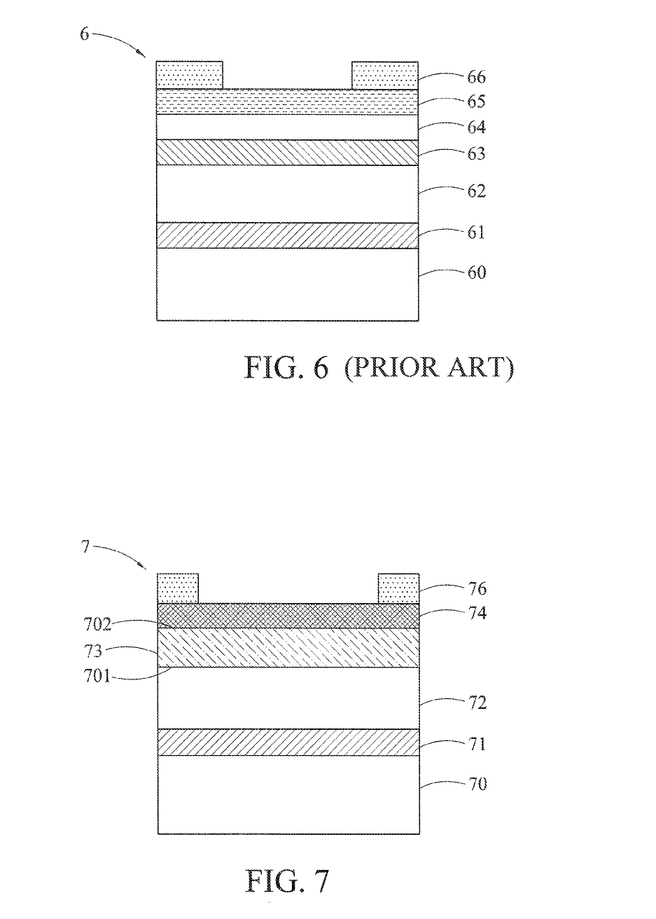

Referring to FIG. 2, a cross-sectional view of a HIT solar cell 2 in accordance with a first embodiment of the present disclosure is shown. The HIT solar cell 2 comprises a p-type crystalline silicon substrate 20, a first intrinsic amorphous silicon thin-film layer 22, an n-type amorphous oxide layer 24, and a first transparent conductive layer 26.

The p-type crystalline silicon substrate 20 has a light-receiving surface 202, and a first intrinsic amorphous silicon thin-film layer 22 is formed on the light-receiving surface 202.

The n-type amorphous oxide layer 24 is formed on the first intrinsic amorphous silicon thin-film layer 22, and the first transparent conductive layer 26 is formed on the n-type amorphous oxide layer 24.

In an embodiment, conductive terminals 28 are formed on the first transparent conductive layer 26 for exposing a portion of the first transparent conductive layer 26 to form a light-receiving area for light to pass through.

The first intrinsic amorphous silicon thin-film layer 22 can be formed by feeding hydrogen, to increase the surface passivation. The conductive terminals 28 can be made of silver or other materials.

The n-type amorphous oxide layer 24 can be processed using an annealing process to improve its structural characteristic. The n-type amorphous oxide layer 24 can be processed using an annealing process to improve its structural characteristic. The n-type amorphous oxide layer 24 can be formed by the annealing process at 100° C. to 1000° C. according to practical needs. In an embodiment, the annealing process is performed at 100° C. to 600° C. With different requirements, the n-type amorphous oxide layer 24 can be made of indium, gallium, zinc, and/or oxygen. For example, the n-type amorphous oxide layer 24 is a-IGZO. The ratio of the elements can be changed according to practical needs. For instance, if the composition of IGZO is formulated as In₁Ga_{X}Zn_{Y}O_{Z}, where 0≦X≦1, 0≦Y≦5 and 1≦Z≦10, the thickness of the n-type amorphous oxide layer 24 may be 1-300 nm substantially, and the energy gap may be between 3.0 eV to 4.0 eV. The n-type amorphous oxide layer 24 formed by a-IGZO can be formed by non-built-in a portionicals arranged in cubic arrangement to increase the transmittance.

The first transparent conductive layer 26 can be made of silicon nitride, silicon dioxide, indium tin oxide, or zinc oxide.

In the HIT solar cell 2 of the first embodiment, a light-against surface 201 opposing the light-receiving surface 202 is provided. The HIT solar cell 2 further comprises a second intrinsic amorphous silicon layer 21, a p-type amorphous silicon layer 23, a second transparent conductive layer 25, and an electrode layer 27.

The second intrinsic amorphous silicon layer 21 is formed on the light-against surface 201. The p-type amorphous silicon layer 23 is formed on the second intrinsic silicon thin-film layer 21. The second transparent conductive layer 25 is formed on the p-type amorphous silicon layer 21. The electrode layer 27 is formed on the second transparent conductive layer 25.

The second intrinsic amorphous silicon layer 21 and the p-type amorphous silicon layer 23 can be formed by feeding hydrogen. The second transparent conductive layer 25 can be made of silicon nitride, silicon dioxide, indium tin oxide, or zinc oxide. The electrode layer 27 can be made of silver. The HIT solar cell of the first embodiment can be designed to have a single light-receiving surface, or can be adjusted to have two light-receiving surfaces.

### Second Embodiment

Referring to FIG. 3, a HIT solar cell 3 of a second embodiment is shown. The HIT solar cell 3 comprises a p-type crystalline silicon substrate 30, an n-type amorphous oxide layer 34, and a first transparent conductive layer 36.

The p-type crystalline silicon substrate 30 has a light-receiving surface 302, and the n-type amorphous oxide layer 34 is formed on the light-receiving surface 302. A first transparent conductive layer 36 is formed on the n-type amorphous oxide layer 34.

In an embodiment, the HIT solar cell 3 further comprises conductive terminals 38 formed on the first transparent conductive layer 36 for exposing a portion of the first transparent conductive layer 36 to form a light-receiving area, for light to pass through. The conductive terminals 38 can be made of silver or other materials.

Similar to the first embodiment, the n-type amorphous oxide layer 34 can be processed by an annealing process to improve its structural characteristic. The n-type amorphous oxide layer 34 can be formed by the annealing process at 100° C. to 1000° C. according to practical needs. In an embodiment, the annealing process is performed at 100° C. to 600° C. With different requirements, the n-type amorphous oxide layer 34 can be made of as indium, gallium, zinc, and/or oxygen. For example, the n-type amorphous oxide layer 34 is a-IGZO. The ratio of the elements can be changed according to practical needs. For instance, if the composition of IGZO is formulated as In₁Ga_{X}Zn_{Y}O_{Z}, where 0≦X≦1, 0≦Y≦5 and 1≦Z≦10, the thickness of the n-type amorphous oxide layer 34 may be 1-300 nm substantially, and the energy gap may be between 3.0 eV to 4.0 eV. The n-type amorphous oxide layer 34 formed by a-IGZO, can be formed by non-built-in a portionicals arranged in cubic arrangement to increase the transmittance. The first transparent conductive layer 36 can be made of silicon nitride, silicon dioxide, indium tin oxide, or zinc oxide.

In comparison with the first embodiment, the HIT solar cell 3 does not have the first intrinsic amorphous silicon thin-film layer 22.

The HIT solar cell 3 can further have the light-against surface 301 opposing the light-receiving surface 302 formed on the other side of the p-type crystalline silicon substrate 30. The HIT solar cell 3 further comprises a second intrinsic amorphous silicon layer 31, a p-type amorphous silicon layer 33, a second transparent conductive layer 35, and an electrode layer 37. The first intrinsic amorphous silicon thin-film layer 31 is formed on the light-against surface 301. The p-type amorphous silicon layer 33 is formed on the first intrinsic silicon film layer 31. The second transparent conductive layer 35 is formed on the p-type amorphous silicon layer 33. The electrode layer 37 is formed on the transparent conductive layer 35. The HIT solar cell 3 of the second embodiment can also be designed with two light-receiving surfaces.

The first intrinsic amorphous silicon thin-film layer 31 and the p-type amorphous silicon layer 33 can be formed by feeding hydrogen. The second transparent conductive layer 35 can be made of silicon nitride, silicon dioxide, indium tin oxide, or zinc oxide. The electrode layer 37 can be made of silver.

In the second embodiment, the n-type amorphous oxide layer 34 of the HIT solar cell 3 can be further divided into an n⁻-type amorphous oxide layer 34a and an n⁺-type amorphous oxide layer 34b. The n⁻-type amorphous oxide layer 34a is formed on the light-receiving surface 302 of the p-type crystalline silicon substrate 30. The n⁺-type amorphous oxide layer 34b is formed on the n⁻-type amorphous oxide layer 34a. The first transparent conductive layer 36 is formed on the n⁺-type amorphous oxide layer 34b. The composition of the n⁻-type amorphous oxide layer 34a is formulated as In₁Ga_{X}Zn_{Y}O_{Z}, where 0≦X≦1, 0≦Y≦5 and 1≦Z≦10. The thickness of the n-type amorphous oxide layer 24 may be 1-300 nm substantially, and the energy gap may be between 3.0 eV to 4.0 eV. The carrier concentration of the n⁻-type amorphous oxide layer 34a can be less than or equal to 10¹⁷ cm³. The carrier concentration of the n⁺-type amorphous oxide layer 34b can be greater than or equal to 10²⁰ cm⁻³. The n⁻-type amorphous oxide layer 34a can be less concentrated than the n⁺-type amorphous oxide layer 34b.

In order to achieve different practical requirements, the n⁻-type amorphous oxide layer 34a is thinner the n⁺-type amorphous oxide layer 34b. In other words, the n⁻-type amorphous oxide layer 34a provides the function of the first intrinsic amorphous silicon thin-film layer 22 of the first embodiment.

### Third Embodiment

Referring to FIG. 5, a solar cell 5 of a third embodiment is shown. The solar cell 5 comprises a p-type nanocrystalline silicon layer 50, a first silver nanowire layer 52, a first n-type amorphous oxide layer 54a, an intrinsic nanocrystalline silicon thin-film layer 51, a second n-type amorphous oxide layer 53, and a second silver nanowire layer 55.

The p-type nanocrystalline silicon layer 50 has a light-receiving surface 502, and an opposing light-against surface 501 of the light-receiving surface. The first silver nanowire layer 52 is formed on the light-receiving surface 502 of the p-type nanocrystalline silicon layer 50. The first n-type amorphous oxide layer 54a is formed on the silver nanowire layer 52. The intrinsic nanocrystalline silicon thin-film layer 51 is formed on the light-against surface 501 of the p-type nanocrystalline silicon layer 50. The second n-type amorphous oxide layer 53 is formed on the intrinsic nanocrystalline silicon thin-film layer 51. The second silver nanowire layer 55 is formed on the second n-type amorphous oxide layer 53.

In the solar cell 5 of the third embodiment, the first n-type amorphous oxide layer 54a is used as a carrier with an intrinsic amorphous silicon layer 54b formed thereon. The p-type amorphous silicon layer 54c is formed on the intrinsic amorphous silicon layer 54b. An transparent conductive layer 56 is formed on the p-type amorphous silicon layer 54c. A glass substrate 58 is formed on the transparent conductive layer 56.

In order to improve the mobility of the semiconductor elements, all types of amorphous or nanocrystalline silicon materials can all be formed by feeding hydrogen. The first and second n-type amorphous oxide layers 54a and 53 can be formed by an annealing process to improve structural characteristics. The first and second n-type amorphous oxide layers 54a and 53 can be formed by the annealing process at 100° C. to 1000° C. according to practical needs. In an embodiment, the annealing process is performed at 100° C. to 600° C. With different requirements, the first and second n-type amorphous oxide layers 54a and 53 can be made of indium, gallium, zinc, and/or oxygen, which has been described previously in the first embodiment. How the first and second silver nanowire layers 52 and 55 are made can be referred to Taiwanese Patent No. I402992. The transparent conductive layer 56 can be made of silicon nitride, silicon dioxide, indium tin oxide, or zinc oxide. Regardless of their transmittance, conductivity and reflectivity, the first and second n-type amorphous oxide layers 54a and 53 and the first and second silver nanowire layers 52 and 55 have shown improved characteristics, as compared to the prior art. Therefore, the present disclosure has large competitive advantages in the conversion efficiency from light to electricity and is more cost effective.

### Fourth Embodiment

Referring to FIG. 7, a solar cell 7 of fourth embodiment is shown. The solar cell 7 comprises an n-type amorphous oxide layer 73 and a silver nanowire layer 74.

The n-type amorphous oxide layer 73 has a light-receiving surface 702, and the silver nanowire layer 74 is formed on the light-receiving surface 702.

In an embodiment, the solar cell 7 further comprises conductive terminals 76 formed on the silver nanowire layer 74 for exposing a portion of the silver nanowire layer 74 to form a light-receiving area, for light to pass through.

In the solar cell 7 according to the present disclosure, the n-type amorphous oxide layer 73 has a light-against surface 701 opposing the light-receiving surface 702. The solar cell 7 further comprises a p-type absorption layer 72, a metallic back contact layer 71, and a substrate 70. The n-type amorphous oxide layer 73 is formed on the p-type absorption layer 72 in a manner that the light-against surface 701 of the n-type amorphous oxide layer 73 is in contact with the p-type absorption layer 72. The p-type absorption layer 72 is formed on the metallic back contact layer 71, and the metallic back contact layer 71 is formed on the substrate 70.

In the fourth embodiment, the n-type amorphous oxide layer 73 is made of indium, gallium, and/or zinc oxide. The conductive terminals 76 are made of nickel or aluminum. The p-type absorption layer 72 is made of copper, indium, gallium, or selenium. How the silver nanowire layer 74 is formed may be referred to Taiwanese Patent No. 1402992.

The n-type amorphous oxide layers 24, 34, 54a and 73 and the second n-type amorphous oxide layer 53 can be formed using sputtering. Compared to the conventional plasma technology, the cost disclosed by the present disclosure is lower, and is therefore more cost-effective. Since the conventional plasma technology is not used herein, the problem of damages caused by plasma can be eliminated.

With regard to the conversion efficiency from light to electricity, the following tables are provided to illustrate the experimental result of the present disclosure. As shown from the tables, regardless the first or second embodiment, even the n-type amorphous oxide, which is thinner than the conventional technology, the present disclosure provides better conversion efficiency as a result of high short circuit current and open circuit voltage. More specifically, in the experiment using the n-type amorphous oxide layer of 10 nm, the first and second embodiment of the present disclosure shows better performances in comparison with the conventional technology. Even comparing the thinner n-type amorphous oxide layer 5 nm of the present disclosure with the n-type amorphous silicon layer of 10 nm of the conventional technology, the performance is better. As shown in the table 4, the second example of the second embodiment disclosed by the present disclosure (i.e., using the n⁻-type amorphous oxide layer and the n⁺-type amorphous oxide layer), the short circuit current density is lower than the first example of the second embodiment (without divided into n⁻-type amorphous oxide layer and n⁺-type amorphous oxide layer), the open circuit voltage is enhanced, thereby further enhancing conversion efficiency.

TABLE 1
simulation data of an HIT solar cell according to the prior art

| n-type | open circuit | short | fill | conversion |
|---|---|---|---|---|
| amorphous | voltage | circuit current | factor | efficiency |
| silicon layer | Voc | density Jsc | F.F. | Eff. |
| thickness | (V) | (mA/cm²) | (%) | (%) |
| 10 nm | 0.682495 | 34.4648 | 70.4237 | 16.5651 |

TABLE 2
simulation data of an HIT solar cell according to
the first embodiment of the present disclosure

| n-type | open circuit | short | fill | conversion |
|---|---|---|---|---|
| amorphous | voltage | circuit current | factor | efficiency |
| oxide layer | Voc | density Jsc | F.F. | Eff. |
| thickness | (V) | (mA/cm²) | (%) | (%) |
| 5 nm | 0.686202 | 36.059 | 69.3298 | 17.1548 |
| 10 nm | 0.686069 | 35.8671 | 69.4708 | 17.0949 |
| 15 nm | 0.685939 | 35.6777 | 69.6093 | 17.0353 |
| 20 nm | 0.68581 | 35.4914 | 69.7443 | 16.976 |

TABLE 3
simulation data of an HIT solar cell according to a first
aspect of the second embodiment of the present disclosure

| n-type | open circuit | short | fill | conversion |
|---|---|---|---|---|
| amorphous | voltage | circuit current | factor | efficiency |
| oxide layer | Voc | density Jsc | F.F. | Eff. |
| thickness | (V) | (mA/cm²) | (%) | (%) |
| 5 nm | 0.694331 | 37.2628 | 68.7875 | 17.7972 |
| 10 nm | 0.694199 | 37.0876 | 68.917 | 17.7435 |
| 15 nm | 0.694067 | 36.9125 | 69.0448 | 17.6891 |
| 20 nm | 0.693936 | 36.7395 | 69.1704 | 17.6349 |

TABLE 4
comparison between simulation data of an HIT solar cell according
to two aspects of the second embodiment of the present disclosure

| | open circuit | short | fill | conversion |
|---|---|---|---|---|
| | voltage | circuit current | factor | efficiency |
| | Voc | density Jsc | F.F. | Eff. |
| | (V) | (mA/cm²) | (%) | (%) |
| a first aspect | 0.694199 | 37.0876 | 68.917 | 17.7435 |
| of the second | | | | |
| embodiment | | | | |
| a second aspect | 0.703361 | 36.9283 | 68.6777 | 17.8383 |
| of the second | | | | |
| embodiment | | | | |

In comparison with the previous technology, the n-type amorphous oxide layer has better transmittance, as well as having remarked improvement of open circuit voltage and short circuit current density, resulting in higher conversion efficiency from light to electricity. Moreover, hydrogen can be fed into the fabricating process, as well as selectively using sputtering and an annealing process can reduce the damages caused by plasma, thereby allowing the structural characteristics to be further improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A heterojunction with intrinsic thin-layer (HIT) solar cell, comprising:
a p-type crystalline silicon substrate having a light-receiving surface;
a first intrinsic amorphous silicon thin-film layer formed on the light-receiving surface of the p-type crystalline silicon substrate;
an n-type amorphous oxide layer formed on the first intrinsic amorphous silicon thin-film layer; and
a first transparent conductive layer, formed on the n-type amorphous oxide layer.

2. The HIT solar cell of claim 1, further comprising conductive terminals formed on the first transparent conductive layer for exposing a portion of the first transparent conductive layer to form a light-receiving area.

3. The HIT solar cell of claim 1, wherein the first intrinsic amorphous silicon thin-film layer is formed by feeding hydrogen, and the n-type amorphous oxide layer is formed by an annealing process.

4. The HIT solar cell of claim 3, wherein the n-type amorphous oxide layer is formed by the annealing process at 100° C. to 1000° C.

5. The HIT solar cell of claim 1, wherein the n-type amorphous oxide layer is made of indium, gallium, zinc, or oxygen.

6. The HIT solar cell of claim 1, wherein the first transparent conductive layer is made of silicon nitride, silicon dioxide, indium tin oxide, or zinc oxide.

7. The HIT solar cell of claim 1, wherein the conductive terminals are made of silver.

8. The HIT solar cell of claim 1, wherein the p-type crystalline silicon substrate has a light-against surface opposing the light-receiving surface, and the HIT solar cell further comprises:
a second intrinsic amorphous silicon thin-film layer formed on the light-against surface of the substrate;
a p-type amorphous silicon layer formed on the second intrinsic amorphous silicon thin-film layer;
a second conductive layer formed on the p-type amorphous silicon layer;
a second conductive layer formed on the p-type amorphous silicon layer; and
an electrode layer formed on the second conductive layer.

9. The HIT solar cell of claim 8, wherein the second intrinsic amorphous silicon thin-film layer is formed by feeding hydrogen, and the n-type amorphous oxide layer is formed by an annealing process.

10. The HIT solar cell of claim 1, wherein the second transparent conductive layer is made of silicon nitride, silicon dioxide, indium tin oxide, or zinc oxide, and the electrode layer is made of silver material.

11. An HIT solar cell, comprising:
a p-type crystalline silicon substrate having a light-receiving surface;
an n-type amorphous oxide layer formed on the light-receiving surface of the p-type crystalline silicon substrate; and
a first transparent conductive layer formed on the n-type amorphous oxide layer.

12. The HIT solar cell of claim 11, further comprising conductive terminals formed on the first transparent conductive layer for exposing a portion of the first transparent conductive layer to form a light-receiving area.

13. The HIT solar cell of claim 11, wherein the n-type amorphous oxide layer is formed by an annealing process.

14. The HIT solar cell of claim 13, wherein the n-type amorphous oxide layer is formed by the annealing process at 100° C. to 1000° C.

15. The HIT solar cell of claim 11, wherein the n-type amorphous oxide layer is made of indium, gallium, zinc, or oxygen.

16. The HIT solar cell of claim 11, wherein the first transparent conductive layer is made of silicon nitride, silicon dioxide, indium tin oxide, or zinc oxide.

17. The HIT solar cell of claim 11, wherein the conductive terminals are made of silver.

18. The HIT solar cell of claim 11, wherein the n-type amorphous oxide layer comprises:
an n⁻-type amorphous oxide layer formed on the light-receiving surface of the p-type crystalline silicon substrate; and
an n⁺-type amorphous oxide layer formed on the n⁻-type amorphous oxide layer,
wherein the first transparent conductive layer is formed on n⁺-type amorphous oxide layer.

19. The HIT solar cell of claim 18, wherein the n⁻-type amorphous oxide layer is thinner than the n⁺-type amorphous oxide layer, and the n⁻-type amorphous oxide layer is less concentrated than the n⁺-type amorphous oxide layer.

20. The HIT solar cell of claim 11, wherein the p-type crystalline silicon substrate further comprises a light-against surface opposing the light-receiving surface, and the HIT solar cell further comprises:
a first intrinsic amorphous silicon thin-film layer formed on the light-against surface of the substrate;
a p-type amorphous silicon layer formed on the first intrinsic amorphous silicon thin-film layer;
a second transparent conductive layer formed on the p-type amorphous silicon layer; and
an electrode layer formed on the second transparent conductive layer.

21. The HIT solar cell of claim 20, wherein the first intrinsic amorphous silicon thin-film layer is formed by feeding hydrogen, and the n-type amorphous oxide layer is formed by feeding hydrogen.

22. The HIT solar cell of claim 20, wherein the second transparent conductive layer is made of silicon nitride, silicon dioxide, indium tin oxide, or zinc oxide, and the electrode layer is made of silver.

23. A solar cell, comprising:
a p-type nanocrystalline silicon layer having a light-receiving surface and an opposing light-against surface;
a first silver nanowire layer formed on the light-receiving surface of the p-type nanocrystalline silicon layer;
a first n-type amorphous oxide layer formed on the first silver nanowire layer;
an intrinsic nanocrystalline silicon thin-film layer formed on the light-against surface of the p-type nanocrystalline silicon layer;
a second n-type amorphous oxide layer formed on the intrinsic nanocrystalline silicon thin-film layer; and
a second silver nanowire layer formed on the second n-type amorphous oxide layer.

24. The solar cell of claim 23, further comprising:
an intrinsic amorphous silicon thin-film layer formed on the first n-type amorphous oxide layer;
a p-type amorphous silicon layer formed on the intrinsic amorphous silicon thin-film layer;
a transparent conductive layer formed on the p-type amorphous silicon layer; and
a glass substrate formed on the transparent conductive layer.

25. The solar cell of claim 23, wherein the first intrinsic nanocrystalline silicon thin-film layer and p-type nanocrystalline silicon layer are formed by feeding hydrogen, and the first and second n-type amorphous oxide layers are formed by an annealing process.

26. The solar cell of claim 25, wherein the first and second n-type amorphous oxide layers str formed by the annealing process at 100° C. to 1000° C.

27. The solar cell of claim 23, wherein the first and second n-type amorphous oxide layers are made of indium, gallium, zinc, or oxygen.

28. The HIT solar cell of claim 1, wherein the transparent conductive layer is made of silicon nitride, silicon dioxide, indium tin oxide, or zinc oxide.

29. The solar cell of claim 24, wherein the intrinsic amorphous silicon thin-film layer and the p-type amorphous silicon layer are formed by feeding hydrogen.

30. A solar cell, comprising:
an n-type amorphous oxide layer having a light-receiving surface; and
a silver nanowire layer formed on the light-receiving surface of the n-type amorphous oxide layer.

31. The solar cell of claim 30, further comprising conductive terminals formed on the silver nanowire layer for exposing a portion of the silver nanowire layer to form a light-receiving area.

32. The solar cell of claim 30, wherein the n-type amorphous oxide layer further has a light-against surface opposing to the light-receiving surface, and the solar cell further comprises:
a substrate;
a metallic back contact layer formed on the substrate; and
a p-type absorption layer formed on the metallic back contact layer, wherein the n-type amorphous oxide layer is formed on the p-type absorption layer in a manner that the light-against surface is in contact with the p-type absorption layer.

33. The solar cell of claim 32, wherein the p-type absorption layer is made of copper, indium, gallium, or selenium.

34. The solar cell of claim 30, wherein the n-type amorphous oxide layer is made of indium, gallium, zinc, or oxygen.

35. The solar cell of claim 30, wherein the conductive terminals are made of nickel or aluminum.
